(19) United States
(12) Patent Application Publication
(10) Pub. No.: US 2026/0353565 A1
(43) Pub. Date: Nov. 5, 2026

(54) ELECTRONIC DEVICE

(71) Applicant: DENSO CORPORATION, Kariya-city (JP)

(72) Inventors: Akihiro FUKATSU, Kariya-city (JP); Noboru NAGASE, Kariya-city (JP); Atsushi SAITO, Kariya-city (JP)

(21) Appl. No.: 19/707,605

(22) Filed: Jun. 15, 2026

Related U.S. Application Data
(63) Continuation of application No. PCT/JP2024/044575, filed on Dec. 17, 2024.

(30) Foreign Application Priority Data
Dec. 18, 2023 (JP) 2023-212729

(51) Int. Cl. H05K 1/181; H05K 1/02; H05K 1/11; H10W 74/10; H10W 90/00; H10W 90/10

(52) U.S. Cl. CPC H05K 1/181; H05K 1/0213; H05K 1/11; H10W 74/111; H10W 90/10; H10W 90/701

(57) ABSTRACT

An electronic device includes a plurality of high-side chips, a plurality of low-side chips, a power supply wiring member, a ground wiring member, and a sealing part. The plurality of low-side chips are respectively connected to the plurality of high-side chips in pairs inside a module. The power supply wiring member connects the plurality of high-side chips to a power supply potential. The ground wiring member connects the plurality of low-side chips to a ground potential. The sealing part seals the plurality of high-side chips, the plurality of low-side chips, the power supply wiring member, and the ground wiring member integrally. The ground wiring member is shared by the plurality of low-side chips.

### CROSS REFERENCE TO RELATED APPLICATIONS

The present application is a continuation application of International Patent Application No. PCT/JP 2024/044575 filed on Dec. 17, 2024, which designated the U.S. and claims the benefit of priority from Japanese Patent Application No. 2023-212729 filed on Dec. 18, 2023. The entire disclosures of all of the above applications are incorporated herein by reference.

### TECHNICAL FIELD

The present disclosure relates to an electronic device.

### BACKGROUND

Conventionally, a semiconductor device in which a semiconductor element is sealed is known. For example, two semiconductor switching elements are sealed in a sealing resin member, and form a half bridge.

### SUMMARY

According to an aspect of the present disclosure, a semiconductor device may include: a plurality of high-side chips each including an upper arm element connected to a high potential side; a plurality of low-side chips respectively connected to the plurality of high-side chips to form a plurality of pairs in a module, the plurality of low-side chips each including a lower arm element connected to a low potential side of a corresponding upper arm element; a power supply wiring member connecting the plurality of high-side chips to a power supply potential; a ground wiring member connecting the plurality of low-side chips to a ground potential; and a sealing part sealing the plurality of high-side chips, the plurality of low-side chips, the power supply wiring member, and the ground wiring member integrally. The ground wiring member may be shared by the plurality of low-side chips. The power supply wiring member may be a power land on which the plurality of high-side chips are arranged. The power land and a ground land connected to the plurality of low-side chips via the ground wiring member may have surfaces exposed from the sealing part on a side adjacent to a substrate to be connected to a power supply pattern and a ground pattern of the substrate, respectively. The power supply pattern and the ground pattern may extend to a back surface of the substrate through vias penetrating the substrate, and be connected to a noise suppression element.

### BRIEF DESCRIPTION OF DRAWINGS

Objects, features, and advantages of the present disclosure will become more apparent from the following detailed description with reference to the accompanying drawings. In the drawings:

FIG. 1 is a plan view of an electronic device according to a first embodiment;

FIG. 2 is a cross-sectional view taken along a line II-II of FIG. 1;

FIG. 3 is a circuit diagram of the electronic device according to the first embodiment;

FIG. 4 is an explanatory diagram for explaining a parasitic inductor;

FIG. 5 is a plan view of an electronic device according to a second embodiment;

FIG. 6 is a plan view of an electronic device according to a third embodiment

FIG. 7 is a plan view of an electronic device according to a fourth embodiment

FIG. 8 is a cross-sectional view taken along line VIII-VIII of FIG. 7;

FIG. 9 is a plan view of the electronic device according to the fourth embodiment;

FIG. 10 is a plan view of an electronic device according to a fifth embodiment

FIG. 11 is a plan view of an electronic device according to a sixth embodiment

FIG. 12 is a cross-sectional view taken along a line XII-XII of FIG. 11;

FIG. 13 is a plan view of an electronic device according to a seventh embodiment;

FIG. 14 is a plan view of an electronic device according to an eighth embodiment;

FIG. 15 is a plan view of an electronic device according to a ninth embodiment; and

FIG. 16 is a cross-sectional view of an electronic device according to another embodiment.

### DETAILED DESCRIPTION

It is assumed that a combination of an upper arm element, which is an element on a high potential side in a bridge circuit, and a lower arm element, which is an element on a low potential side, is defined as an arm. In a case where multiple arms are integrally modularized, if wiring is not shared, a difference in parasitic inductors between phases becomes large, and switching loss and surge voltage are likely to increase. The present disclosure provides an electronic device capable of reducing an inter-phase difference in parasitic inductors.

According to an aspect of the present disclosure, an electronic device includes: a plurality of high-side chips, a plurality of low-side chips, a power supply wiring member, a ground wiring member, and a sealing part. The high-side chips include upper arm elements connected to a high potential side. The low-side chips are respectively connected to the high-side chips in a module to form pairs, and include lower arm elements respectively connected to the upper arm elements on a low potential side.

The power supply wiring member connects the high-side chips to a power supply potential. The ground wiring member connects the low-side chips to a ground potential. The sealing part seals the high-side chips, the low-side chips, the power supply wiring member, and the ground wiring member integrally. The ground wiring member is shared by the plurality of low-side chips. Accordingly, an inter-phase difference in parasitic inductors can be reduced.

Hereinafter, multiple embodiments of the present disclosure will be described with reference to the drawings. In the multiple embodiments described hereinafter, substantially identical configurations are denoted by the same reference numerals, and the description thereof will not be repeated.

### First Embodiment

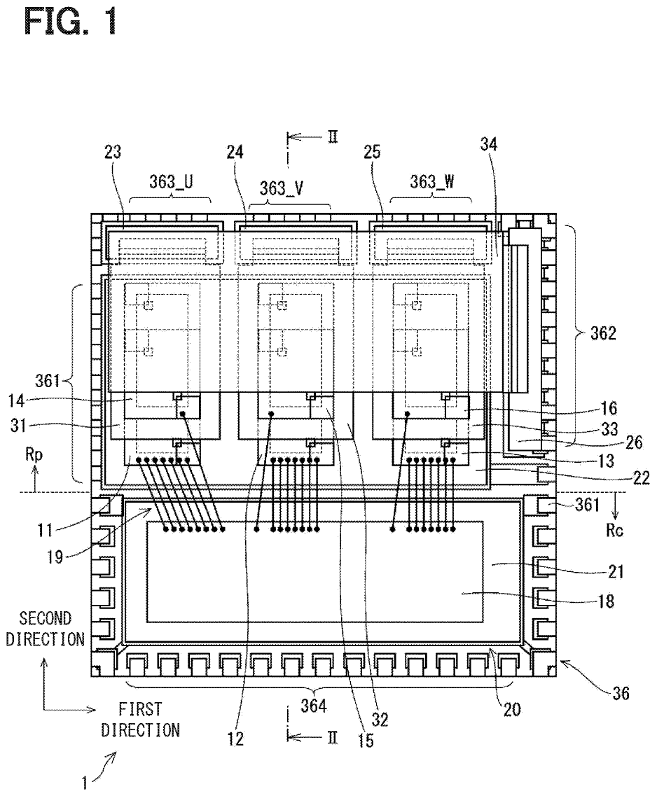

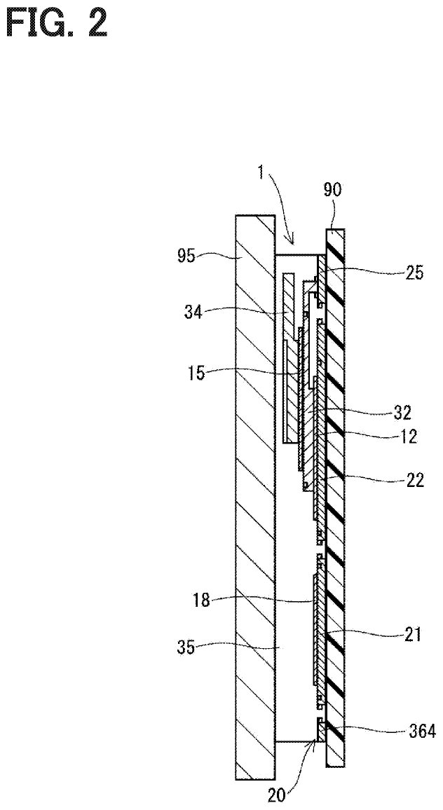

A first embodiment is shown in FIGS. 1 to 3. As shown in FIGS. 1 and 2, an electronic device 1 includes high-side chips 11 to 13, low-side chips 14 to 16, a control chip 18, a lead frame 20, clips 31 to 34, a sealing part 35, and the like. The chips 11 to 16 and 18, the lead frame 20, and the clips 31 to 34 are integrally sealed by the sealing part 35 so that the electronic device 1 has a substantially rectangular shape in a plan view as a whole, and heat can be dissipated to a heat dissipation portion 95 disposed on a top surface side. For the sake of description, illustration of the sealing part 35 is omitted in FIG. 1 and the like, and hatching of the sealing part 35 is omitted in FIG. 2.

Terminals 36 are disposed at an outer peripheral portion of the sealing part 35. The terminals 36 may be of a non-lead type, or may be a lead type in which a lead protrudes. The terminals 36 include a power supply terminal 361, a ground terminal 362, an output terminal 363, and a signal terminal 364. In the drawings, the reference numeral of the output terminal 363 is indicated with a sign of a corresponding phase in such a manner as “363_U”. In a control region Rc, terminals disposed at lateral sides can be used as the signal terminal 364. However, among the terminals connected to a control land 21, a terminal arranged adjacent to a boundary with a power region Rp is assigned to a power supply terminal or a ground terminal related to power feeding to a pre-driver integrated circuit (IC) 180.

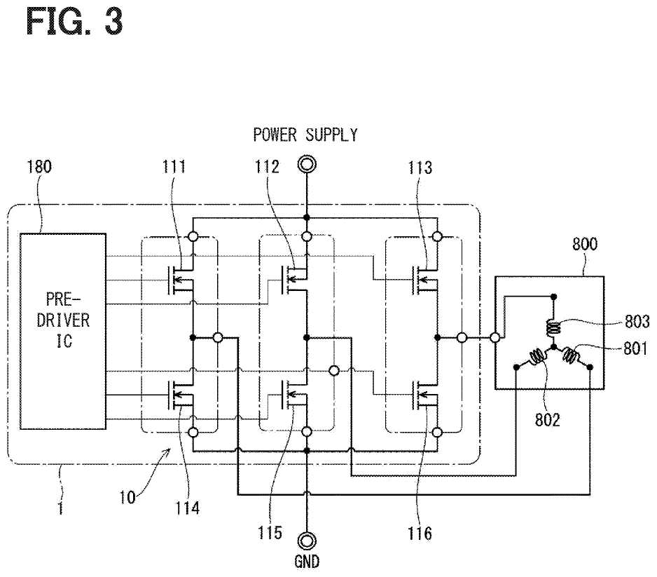

The high-side chips 11 to 13 incorporate upper arm elements 111 to 113, and the low-side chips 14 to 16 incorporate lower arm elements 114 to 116 (see FIG. 3). The upper arm elements 111 to 113 and the lower arm elements 114 to 116 of the present embodiment are metal oxide semiconductor field effect transistors (MOSFETs), but may be insulated gate bipolar transistors (IGBTs), bipolar transistors, or the like. Each of the high-side chips 11 to 13 and the low-side chips 14 to 16 has a source electrode on a top surface side thereof and a drain electrode on a back surface side thereof. The high-side chips 11 to 13 and the low-side chips 14 to 16 are connected to the control chip 18 through signal lines 19. The signal lines 19 include a signal line for gate driving, a signal line for current detection, a signal line for temperature detection, and the like.

As shown in FIG. 3, the upper arm elements 111 to 113 and the lower arm elements 114 to 116, which are six switching elements, are bridge-connected to constitute a driver circuit 10 for driving a motor 800 as a load. Drains of the upper arm elements 111 to 113 are connected to a power supply, and sources of the upper arm elements 111 to 113 are connected to drains of the lower arm elements 114 to 116, which are correspondingly provided. Sources of the lower arm elements 114 to 116 are connected to a ground. Gates of the upper arm elements 111 to 113 and the lower arm elements 114 to 116 are connected to the pre-driver IC 180 incorporated in the control chip 18.

A connection point between the upper arm element 111 and the lower arm element 114, which are paired and provided for a U phase, is connected to one end of a motor winding 801 of the U phase. A connection point between the upper arm element 112 and the lower arm element 115, which are paired and provided for a V phase, is connected to one end of a motor winding 802 of the V phase. A connection point between the upper arm element 113 and the lower arm element 116, which are paired and provided for a W phase, is connected to one end of a motor winding 803 of the W phase. The other ends of the motor windings 801 to 803 are wired together. The connection of the motor windings 801 to 803 is not limited to a Y-connection, and may be a Δ-connection.

Returning to FIGS. 1 and 2, the lead frame 20 includes lands 21 to 26. A back surface of the lead frame 20 is exposed from the sealing part 35, and is electrically connected to a wiring pattern of a substrate 90 by solder bonding or the like. Note that it is not always necessary that all the lands are connected to the substrate 90 on a back surface side. Each of the lands 21 to 26 is formed integrally with the terminal 36 or is connected to the terminal 36 at a side of the outer peripheral portion of the sealing part 35. The control chip 18 is placed on a control land 21, and the high-side chips 11 to 13 are placed on a power land 22.

The control chip 18 has a substantially rectangular shape in a plan view. Hereinafter, a direction parallel to a long side of the control chip 18 is referred to as a “first direction”, and a direction orthogonal to the first direction, i.e., a direction parallel to a short side of the control chip 18 is referred to as a “second direction”. Further, inside a mold, i.e., in the sealing part 35, a side adjacent to the lead frame 20 will be referred to as a “lower side”, and a side opposite to the lead frame 20 will be referred to as the top surface side or an “upper side”.

The lands 21 to 25 are arranged in an order of the control land 21, the power land 22 and three output lands 23 to 25 from one side (i.e., a bottom side in FIG. 1) in the second direction. A ground land 26 is arranged adjacent to the power land 22 and the output land 25. The control land 21 is at a ground potential, and uses the terminals that are arranged at both the short sides and the long side, which is on a side further from the power land 22, as the signal terminal 364.

The power land 22 is arranged adjacent to a long side of the control land 21. The power land 22 is in contact with a power supply pattern of the substrate 90 on a back surface side, and is at a power supply potential. The power land 22 uses the terminals that are arranged at a side, which is on a side opposite to the ground land 26 in the first direction, as the power supply terminal 361. The high-side chips 11 to 13 are arranged side by side on the power land 22 and are oriented in such a manner that each of the high-side chips 11 to 13 has the source on the upper side, the drain on the lower side and the gate facing the long side of the control chip 18. The drain electrodes of the high-side chips 11 to 13 are connected to the power land 22.

The output lands 23 to 25 are arranged side by side adjacent to the power land 22 on a side opposite to the control land 21. The output terminals 363 are formed at end portions of the output lands 23 to 25 on a side opposite to the power land 22 in the second direction. The output terminals 363 are connected to the motor windings of the respective phases via substrate wirings (not shown) or the like. The ground terminal 362 is formed at an end portion of the ground land 26 on a side opposite to the land 25 in the first direction.

Intermediate clips 31 to 33 are respectively placed on the high-side chips 11 to 13. The intermediate clips 31 to 33 are conductive metal plates, such as copper plates. The intermediate clips 31 to 33 each have a plate shape wider than the corresponding chip 11 to 16. The intermediate clips 31 to 33 are connected to the high-side chips 11 to 13 and the low-side chips 14 to 16 at first ends thereof and to the output lands 23 to 25 at second ends thereof. The intermediate clips 31 to 33 are arranged in such a manner that an edge of the first end of each of the intermediate clips 31 to 33 is shifted from an edge of the corresponding high-side chip 11 to 13 on the control chip 18 side to be away from the control chip 18, thereby enabling the gate electrode of the corresponding high-side chip 11 to 13 to be connected to the control chip 18.

The low-side chips 14 to 16 are arranged on the upper side of the intermediate clips 31 to 33. The low-side chips 14 to 16 are arranged such that the drains are on the lower side, the sources are on the upper side and the gates face the long side of the control chip 18. Thus, the sources of the high-side chips 11 to 13 and the drains of the low-side chips 14 to 16 are connected by the intermediate clips 31 to 33, respectively. The second ends of the intermediate clips 31 to 33 are bent toward the lower side, and are connected to the output lands 23 to 25, respectively.

A ground clip 34 is a conductive plate, such as a copper plate. The ground clip 34 has a plate shape. The ground clip 34 covers the upper sides of the low-side chips 14 to 16. The ground clip 34 is bent toward the lower side at an end portion in the first direction, and is connected to the ground land 26. In the electronic device 1, the drain electrodes of the high-side chips 11 to 13 are connected by the power land 22, which is a metal plate commonly provided, and the source electrodes of the low-side chips 14 to 16 are connected by the ground clip 34, which is a metal plate commonly provided.

The ground clip 34 is arranged in such a manner that an end portion of the ground clip 34 on the control chip 18 side is shifted from the end portions of the low-side chips 14 to 16 on the control chip 18 side to be away from the control chip 18, thereby enabling the gates of the low-side chips 14 to 16 to be connected to the control chip 18.

The ground clip 34 is formed to be wide so as to cover the upper sides of the bent portions of the second ends of the intermediate clips 31 to 33. By forming the area of the ground clip 34 as large as possible, a heat dissipation efficiency can be enhanced. It is preferable to reduce the thickness of the sealing part 35 on the upper side of the ground clip 34 in terms of the heat dissipation.

In the electronic device 1, the control chip 18 is disposed in an area on one side in the second direction, and the chips 11 to 16 constituting the driver circuit 10 are disposed in an area on the other side. Further, the power region Rp to which a relatively large current is applied and the control region Rc to which a relatively small current is applied are consolidated and arranged in separate regions. In the power region Rp, from the lower side, the power land 22, the high-side chips 11 to 13, the intermediate clips 31 to 33, the low-side chips 14 to 16, and the ground clip 34 are stacked in this order, thereby forming a stacked structure.

Further, the chips 11 to 16 are arranged so that the gate electrodes face the control chip 18, and the power land 22, the high-side chips 11 to 13, the intermediate clips 31 to 33, the low-side chips 14 to 16, and the ground clip 34 are stacked and shifted in a stepped manner so as to enable the connection of the gate electrodes to the control chip 18, so that each of the chips 11 to 16 has a non-overlapping region that does not overlap a member stacked on the upper side thereof. Thus, the chips 11 to 16 can be connected to the control chip 18 by wire bonding using the signal lines 19. Further, in the control chip 18, connection positions with the gate electrodes of the chips 11 to 16 are consolidated at one side adjacent to the chips 11 to 16.

In the electronic device 1, in the power region Rp, the power supply terminal 361 is arranged on the one side in the first direction, the ground terminal 362 is arranged on the other side in the first direction. Further, the output terminal 363 is arranged at the end portion in the second direction. Thus, when viewed as a whole, the power supply and the ground are input in the first direction, and the electric power related to motor driving is output in the second direction. As a result, the wiring connecting the power supply and the ground in the power region Rp and the signal line 19 of the control chip 18 can be separated from each other, and an influence of noise or surge can be reduced. In addition, the power land 22 having the power supply potential and the ground land 26 are arranged adjacent to each other. Therefore, a loop of a power portion serving as a noise source becomes small, so that noise can be reduced.

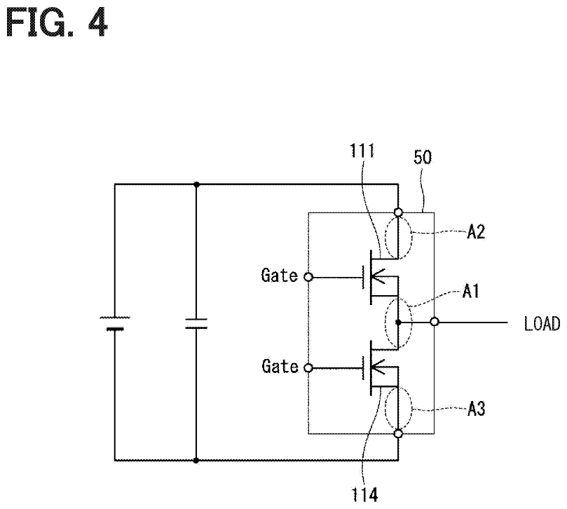

FIG. 4 is an explanatory diagram for explaining a parasitic inductor (hereinafter, “ESL”) in the driver circuit 10. In this case, a U-phase arm will be described as an example. When a large current is applied to the electronic device 1, a magnetic field is generated around the electronic device 1, and a part enclosed by a broken-line circle in FIG. 4 becomes the ESL. Energy accumulated in this part is applied to the element, resulting in a switching loss. For example, as a reference example, in a case where an upper arm element is arranged on one side of a control chip, a lower arm element is arranged on the other side of the control chip, and a source of the upper arm element and a drain of the lower arm element are connected by a substrate wiring outside a module, a wiring length becomes long, so that the ESL becomes large.

In the present embodiment, the sources of the high-side chips 11 to 13 and the drains of the low-side chips 14 to 16 are connected on opposite faces of the intermediate clips 31 to 33. That is, since the wiring length between the drain and the source indicated by A1 in FIG. 4 corresponds to a thickness of the intermediate clips 31 to 33, the wiring length is shorter than that in the case of connecting via the substrate wiring or the like outside the module. Therefore, it is possible to reduce the ESL.

Further, the drains of the upper arm elements 111 to 113 indicated by A2 in FIG. 4 are connected to the power land 22, which are provided commonly for the three phases, and the sources of the lower arm elements 114 to 116 indicated by A3 in FIG. 4 are connected by the ground clip 34, which are provided commonly for the three phases. Therefore, since an ESL difference between the phases is eliminated, switching of freewheeling current becomes fast, and switching loss can be reduced.

The control chip 18 constituting the pre-driver IC 180 is disposed inside the module and the gate signal line is wired inside the module. Since it is not necessary to have vias or the like, as compared to the case where the gate wiring is provided on a printed circuit board, for example, the ESL can be reduced.

As described above, the electronic device 1 includes the plurality of high-side chips 11 to 13, the plurality of low-side chips 14 to 16, the power land 22, and the ground clip 34, and the sealing part 35. The high-side chips 11 to 13 include the upper arm elements 111 to 113, which are connected to the high potential side. The low-side chips 14 to 16 include the lower arm elements 114 to 116, which are connected to the low potential side of the respective upper arm elements 111 to 113, and are connected to the respective high-side chips 11 to 13 forming pairs inside the module. Specifically, the high-side chip 11 and the low-side chip 14, which form the pair for the U-phase, are connected to each other. The high-side chip 12 and the low-side chip 15, which form the pair for the V-phase, are connected to each other. The high-side chip 13 and the low-side chip 16, which form the pair for the W-phase, are connected to each other.

The power land 22, which serves as a power supply wiring member, connects the high-side chips 11 to 13 to a power supply potential. The ground clip 34, which serves as a ground wiring member, connects the low-side chips 14 to 16 to a ground potential. The sealing part 35 seals the high-side chips 11 to 13, the low-side chips 14 to 16, the power land 22, and the ground clip 34 integrally.

The ground clip 34 is shared by the plurality of low-side chips 14 to 16. Further, the power land 22 is shared by the plurality of high-side chips 11 to 13. Accordingly, since the ESL of each phase is made common, a surge voltage difference and a switching loss difference between the arms can be reduced.

In the present embodiment, the power supply wiring member is the power land 22 on which the high-side chips 11 to 13 are arranged, and the power land 22 is arranged adjacent to the ground land 26 connected to the ground clip 34. Accordingly, a wiring distance between the power supply and the ground is shortened, and thus the ESL can be reduced.

An intermediate connection member connecting each of the plurality of high-side chips 11 to 13 and the paired low-side chip 14 to 16 is composed of two or fewer members. In the present embodiment, the high-side chip 11, the intermediate clip 31, and the low-side chip 14 paired with the high-side chip 11 are stacked in this order, and the high-side chip 11 and the low-side chip 14 are connected on both surfaces of the intermediate clip 31. Likewise, the high-side chip 12, the intermediate clip 32, and the low-side chip 15 paired with the high-side chip 12 are stacked in this order, and the high-side chip 12 and the low-side chip 15 are connected on both surfaces of the intermediate clip 32. Furthermore, the high-side chip 13, the intermediate clip 33, and the low-side chip 16 paired with the high-side chip 13 are stacked in this order, and the high-side chip 13 and the low-side chip 16 are connected on both surfaces of the intermediate clip 33. That is, in the present embodiment, each of the high-side chips 11 to 13 and each of the low-side chips 14 to 16 forming a pair are connected by a corresponding one of the intermediate clips 31 to 33.

By reducing the number of intermediate connection members as much as possible, a wiring length can be shortened, and the ESL can be reduced. Further, the electronic device 1 can be reduced in size by configuring the high-side chips 11 to 13, the intermediate clips 31 to 33, and the low-side chips 14 to 16 into a stacked structure.

The intermediate clips 31 to 33 and the low-side chips 14 to 16 are arranged on a top surface side of the high-side chips 11 to 13, and are stacked in a shifted state without overlapping a part of the high-side chips 11 to 13. By stacking the intermediate clips 31 to 33 and the low-side chips 14 to 16 in a shifted manner and securing a non-overlapping region on the top surface side of each of the high-side chips 11 to 13, it is possible to appropriately connect the signal lines 19.

The electronic device 1 includes the control chip 18 that incorporates the pre-driver IC 180 configured to output drive signals for the upper arm elements 111 to 113 and the lower arm elements 114 to 116, and the control chip 18 is sealed in the sealing part 35. The high-side chips 11 to 13 and the low-side chips 14 to 16 are arranged in an area on one side of the control chip 18 in the second direction, such that gate electrodes face the control chip 18. By incorporating the control chip 18, the number of terminals can be reduced. Furthermore, by collectively arranging the high-side chips 11 to 13 and the low-side chips 14 to 16 on one side of the control chip 18, the control region Rc and the power region Rp can be separated.

### Second Embodiment

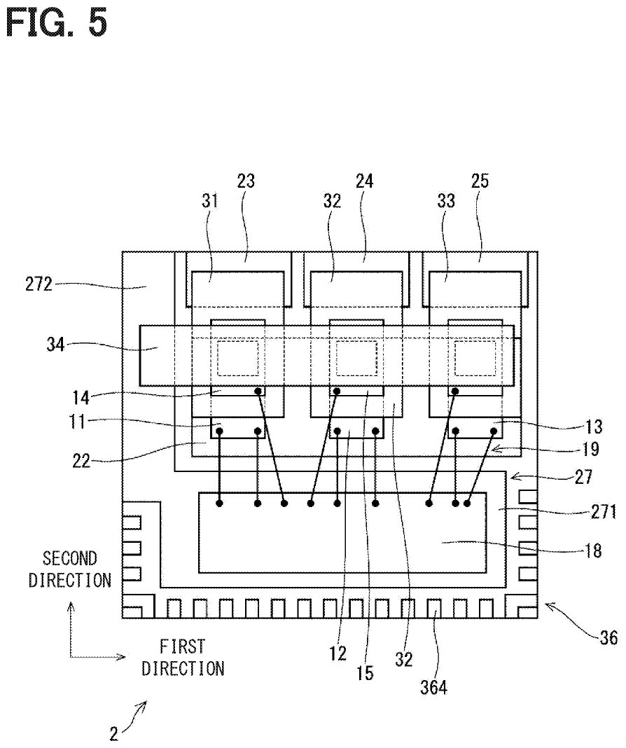

A second embodiment is shown in FIG. 5. In an electronic device 2 of the second embodiment, arrangements, connections, and the like of the chips 11 to 16 are similar to those in the first embodiment. FIG. 5 is shown in a simplified manner so that terminals other than signal terminals are omitted, signal lines are described mainly with respect to gate signal lines, and other signal lines are omitted as appropriate. The same applies to drawings relating to embodiments described later. In the present embodiment, a land 27, which serves as the ground land, includes a control land 271 on which the control chip 18 is placed and a ground land 272 to which the ground clip 34 is connected. The control land 271 is formed integrally with the ground land 272. The control land 271 is arranged adjacent to the power land 22 in the second direction. The ground land 272 is arranged adjacent to the power land 22 in the first direction. Even with this configuration, the electronic device 2 of the second embodiment achieves the similar effects to those of the electronic device 1 of the first embodiment described above.

### Third Embodiment

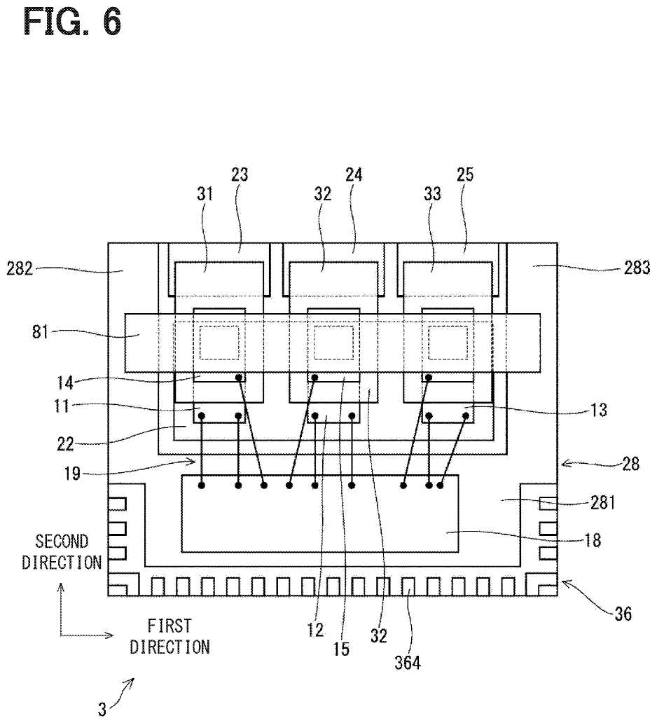

A third embodiment is shown in FIG. 6. In an electronic device 3 of the third embodiment, arrangements and the like of the chips 11 to 16 are similar to those of the first embodiment. A land 28, which serves as the ground land of the present embodiment, includes a control land 281 and ground lands 282 and 283. The control chip 18 is placed on the control land 281. The control land 281 is formed integrally with the ground lands 282 and 283. The ground lands 282 and 283 are formed on both sides of the power land 22 in the first direction.

A ground clip 81 is arranged on an upper side of the low-side chips 14 to 16 The ground clip 81 is bent to the lower side at both ends in the first direction to be connected to the ground lands 282 and 283. By arranging the ground lands 282 and 283 on both sides in the first direction, a connection can be made with a ground pattern of a substrate from either side, and thus a degree of freedom in a substrate layout is improved. Moreover, the similar effects to those of the above embodiments are achieved.

### Fourth Embodiment

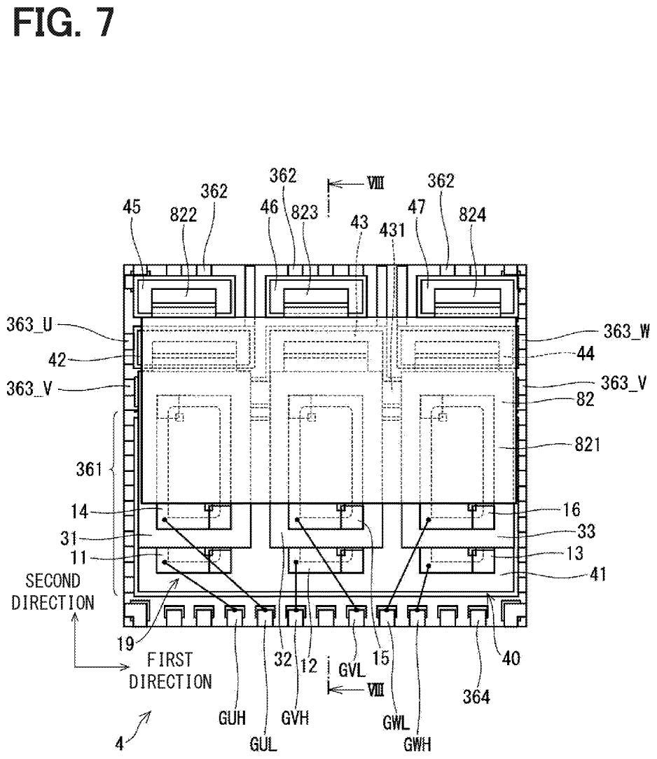

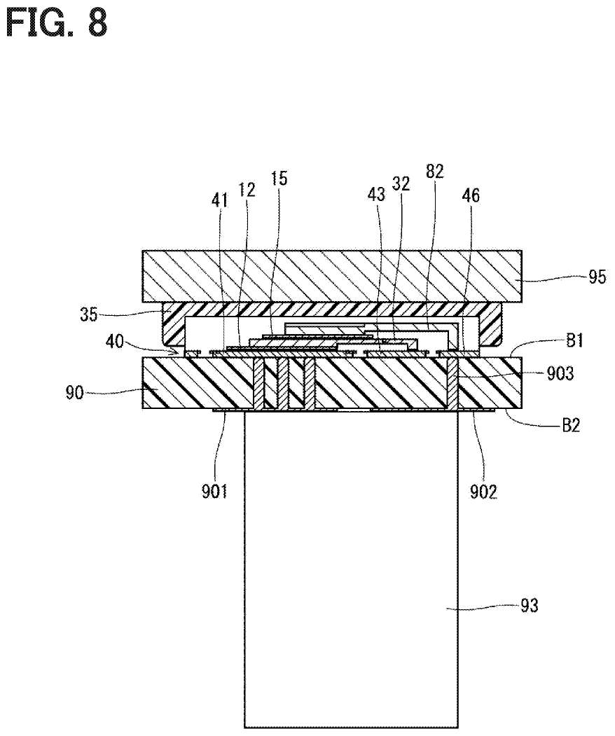

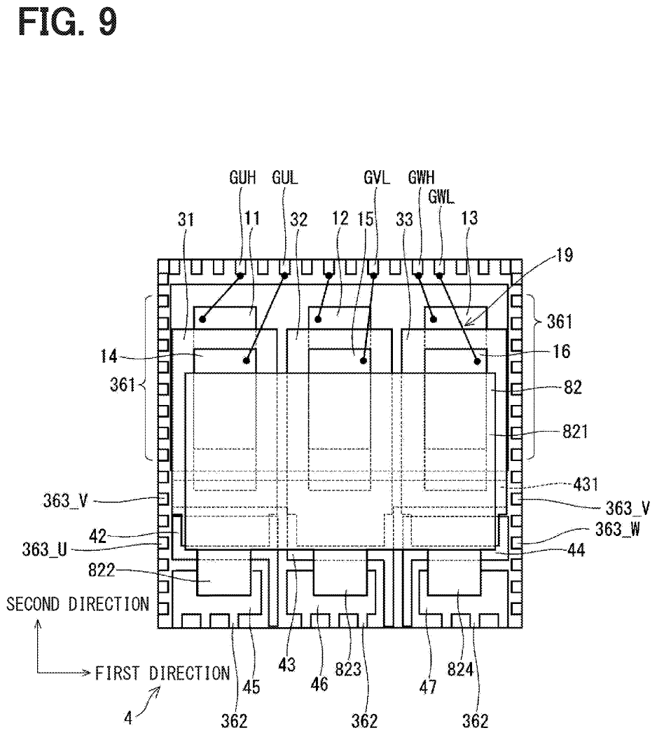

A fourth embodiment is shown in FIGS. 7 to 9. In a cross-sectional view of FIG. 8, hatching of a capacitor 93 is omitted. FIG. 9 schematically shows FIG. 7, and is turned upside down from FIG. 7. A lead frame 40 of an electronic device 4 has a power land 41, output lands 42 to 44, and ground lands 45 to 47. In the present embodiment, the electronic device 4 does not include a control chip. However, the electronic device 4 may include the control chip, similarly to the embodiments described above. The same applies to a sixth embodiment and a seventh embodiment described hereinbelow.

The power land 41 is substantially the same as the power land 22 of the embodiment described above, and the high-side chips 11 to 13 are arranged side by side. The intermediate clips 31 to 33 are arranged on the high-side chips 11 to 13, and the low-side chips 14 to 16 are stacked on the intermediate clips 31 to 33. At the first ends of the intermediate clips 31 to 33, the high-side chips 11 to 13 and the low-side chips 14 to 16 are connected to opposite faces of the intermediate clips 31 to 33, and the second ends of the intermediate clips 31 to 33 are connected to the output lands 42 to 44. A stacked structure of the chips 11 to 16 is similar to that in the embodiment described above. Moreover, gate terminals GUH, GUL, GVH, GVL, GWH, and GWL are allocated to terminals on one side in the second direction.

The output lands 42 to 44 are arranged between the power land 41 and the ground lands 45 to 47 in the second direction. The output land 43 arranged in the middle in the first direction is provided with terminal connection portions 431 extending to both sides in the first direction. The output lands 42 and 44 are arranged on both sides of the output land 43 on a ground land side of the terminal connection portions 431. The output terminals 363 connected to the output lands 42 to 44 are arranged at the sides in the first direction.

The ground lands 45 to 47 are arranged on a side opposite to the power land 41 across the output lands 42 to 44. That is, in the present embodiment, the power land 41, the terminal connection portions 431 of the output land 43, the output lands 42 to 44, and the ground lands 45 to 47 are arranged in this order from one side in the second direction. The ground terminals 362 connected to the ground lands 45 to 47 are arranged on a side opposite to the gate terminals in the second direction.

A ground clip 82 has a base portion 821 and protruding portions 822 to 824. The base portion 821 is arranged so as to be shifted such that it does not overlap with gate electrodes of the low-side chips 14 to 16 and is arranged so as to cover an upper side of the low-side chips 14 to 16. The protruding portions 822 to 824 are bent to the lower side, and are connected to the ground lands 45 to 47. The ground clip 82 of the present embodiment is arranged so as to cover an upper side of the intermediate clips 31 to 33.

As shown in FIG. 8, the power land 41, which is at a power supply potential, and the ground lands 45 to 47 are exposed from the sealing part 35 on the lower side, and are electrically connected to a power supply pattern 901 and a ground pattern 902 of a substrate 90 by a solder connection or the like. In other words, the electronic device 4 is connected to the substrate 90 by a back surface connection.

Assuming that a mounting surface of the substrate 90 on a side where the electronic device 4 is mounted is referred to as a first mounting surface B1 and an opposite mounting surface of the substrate 90 is referred to as a second mounting surface B2, the power supply pattern 901 and the ground pattern 902 are formed to extend to the second mounting surface B2 side through vias 903. A capacitor 93 is connected to the power supply pattern 901 and the ground pattern 902 on the second mounting surface B2 side. That is, the capacitor 93 is provided on a back surface of the driver circuit 10, and is connected by the common power supply pattern 901 and ground pattern 902. Accordingly, since a wiring length between the driver circuit 10 and the capacitor 93 can be shortened, the ESL can be reduced with high efficiency. Similarly, in embodiments other than the present embodiment, the capacitor may be connected to the power supply pattern and the ground pattern on the second mounting surface side at which the electronic device has the back surface side connection.

In the present embodiment, the power land 41 and the ground lands 45 to 47 connected to the low-side chips 14 to 16 via the ground clip 82 have surfaces exposed from the sealing part 35 on a side in contact with the substrate 90, and are respectively connected to the power supply pattern and the ground pattern of the substrate 90.

The power supply pattern 901 and the ground pattern 902 are formed to extend to the back surface side through the vias 903 penetrating the substrate 90, and are connected to the capacitor 93. Accordingly, the ESL can be reduced with high efficiency.

### Fifth Embodiment

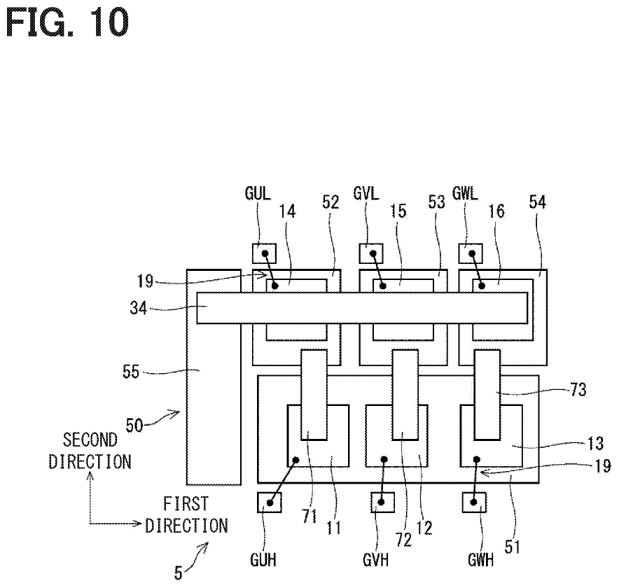

A fifth embodiment is shown in FIG. 10. In the present and subsequent embodiments, the high-side chips 11 to 13 and the low-side chips 14 to 16 are not stacked, but are arranged to be flatly, that is, arranged in a planar direction. A lead frame 50 of an electronic device 5 of the present embodiment has a power land 51, output lands 52 to 54, and a ground land 55.

The high-side chips 11 to 13 are arranged on the power land 51, and drain electrodes provided on back surfaces of the high-side chips 11 to 13 are connected to the power land 51. Source electrodes provided on upper surfaces of the high-side chips 11 to 13 are connected to intermediate clips 71 to 73. The intermediate clips 71 to 73 are arranged so as to cover upper surfaces of the high-side chips 11 to 13 in a state in which gate electrodes of the high-side chips 11 to 13 and gate terminals are connectable. The intermediate clips 71 to 73 are bent toward the lower side at first end one end portion on a side in the second direction, and are connected to the output lands 52 to 54.

The output lands 52 to 54 are arranged adjacent to the power land 51 in the second direction, and the low-side chips 14 to 16 are arranged on the output lands 52 to 54. Drain electrodes provided on back surfaces of the low-side chips 14 to 16 are connected to the output lands 52 to 54. That is, the source electrodes of the high-side chips 11 to 13 and the drain electrodes of the low-side chips 14 to 16 are connected via two members, namely, the intermediate clips 71 to 73 and the output lands 52 to 54.

That is, in the present embodiment, the intermediate clips 71 to 73 and the output lands 52 to 54 correspond to an “intermediate connection member”, and the number of intermediate connection members connecting the U-phase high-side chip 11 and low-side chip 14 forming a pair is two. Similarly, the number of intermediate connection members connecting the V-phase high-side chip 12 and low-side chip 15 forming a pair is two, and the number of intermediate connection members connecting the W-phase high-side chip 13 and low-side chip 16 forming a pair is two.

The ground land 55 is arranged adjacent to the power land 51 and the output land 52 in the first direction. The ground clip 34 is substantially the same as that of the first embodiment except that it is narrower than that of the first embodiment. The ground clip 34 covers upper surfaces of the low-side chips 14 to 16, and is bent to the lower side at a portion adjacent to the ground land 55 to be connected to the ground land 55.

Gate electrodes of the chips 11 to 16 are connected to the gate terminals at portions not covered with the clips 71 to 73 and 34. In the present embodiment, a control IC is not included in a module. Gate terminals connected to the gate electrodes of the high-side chips 11 to 13 are provided on one side in the second direction, and gate terminals connected to gate electrodes of the low-side chips 14 to 16 are provided on the other side in the second direction. Even with this configuration, the similar effects to those of the embodiments described above are achieved.

### Sixth Embodiment, Seventh Embodiment

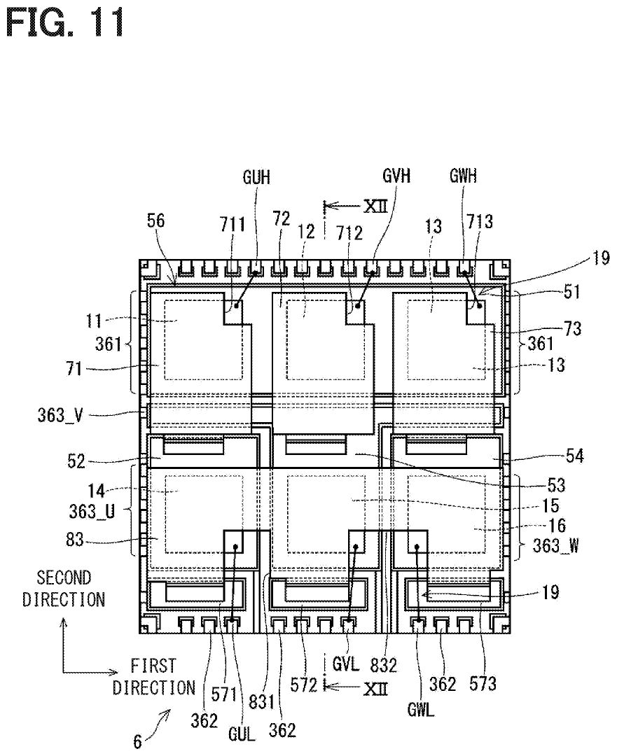

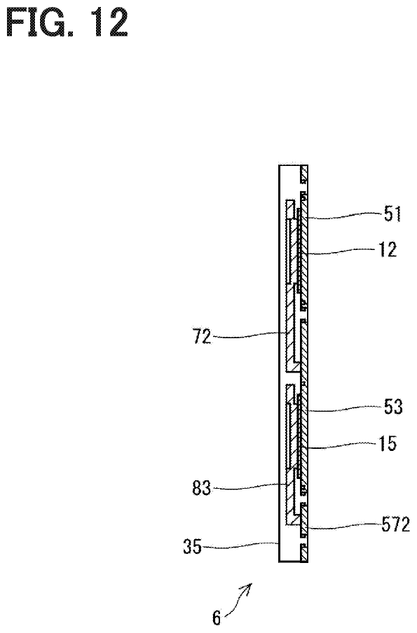

A sixth embodiment is shown in FIGS. 11 and 12. A lead frame 56 of an electronic device 6 of the sixth embodiment is different from that of the fifth embodiment in that ground lands 571 to 573 are arranged on a side opposite to the power land 51 across the output lands 52 to 54. That is, in the present embodiment, the power land 51, the output lands 52 to 54, and the ground lands 571 to 573 are arranged in this order from one side in the second direction.

The intermediate clips 71 to 73 are formed with cutout portions 711 to 713 for connecting gate electrodes of the high-side chips 11 to 13 to gate terminals. The cutout portions 711 to 713 are provided at corner portions on end portions on a side opposite to the output lands 52 to 54.

A ground clip 83 is arranged on an upper side of the low-side chips 14 to 16. Three protruding portions of the ground clip 83 formed on a side adjacent to the ground lands 571 to 573 are bent to the lower side, and are connected to the ground lands 571 to 573, respectively. The ground clip 83 is formed with cutout portions 831 and 832 such that gate electrodes of the low-side chips 14 to 16 provided on the ground lands 571 to 573 side and gate terminals are connectable. The cutout portion 831 is provided at a position corresponding to the gate electrode of the U-phase low-side chip 14. The cutout portion 832 is provided at a position corresponding to gate electrodes of the V-phase and W-phase low-side chips 15 and 16 provided adjacently.

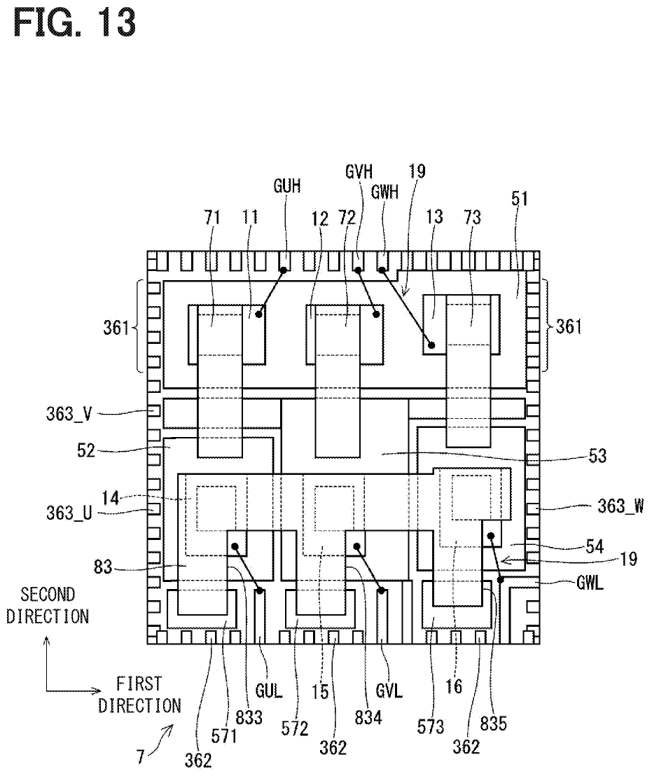

An electronic device 7 of the seventh embodiment shown in FIG. 13 is a modification of the sixth embodiment, and the intermediate clips 71 to 73 are formed to be narrower than the high-side chips 11 to 13. Gate electrodes of the high-side chips 11 to 13 are connected to gate terminals on a side of the intermediate clips 71 to 73 in the first direction. Further, the ground clip 83 is formed with cutout portions 833 to 835 for connecting gate electrodes of the low-side chips 14 to 16 and gate terminals for respective phases.

In the sixth embodiment, a position in the second direction of the W-phase low-side chip 16 is arranged to be shifted from the U-phase and V-phase low-side chips 14 and 15, but a shift of an extent that source electrodes are connectable by the common ground clip 83 is allowed, and is considered as “arranged side by side”. Further, a similar shift is also allowed for the high-side chips 11 to 13. Even with this configuration, the similar effects to those of the above embodiments are achieved.

### Eighth Embodiment, Ninth Embodiment

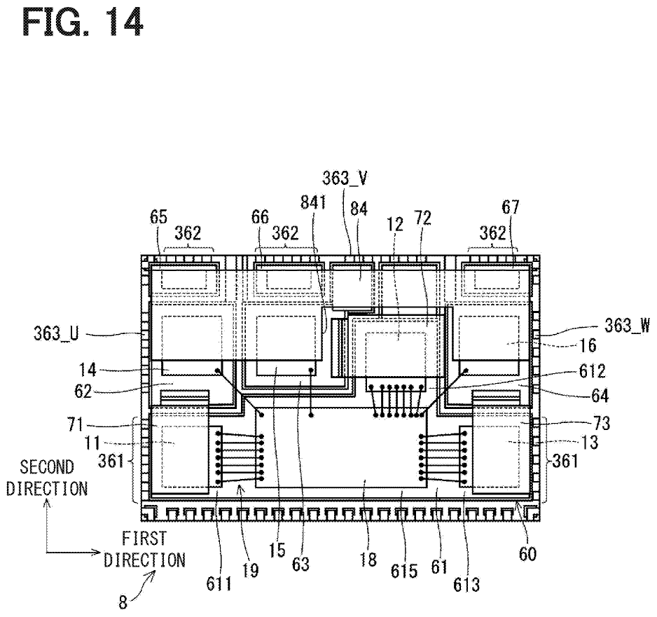

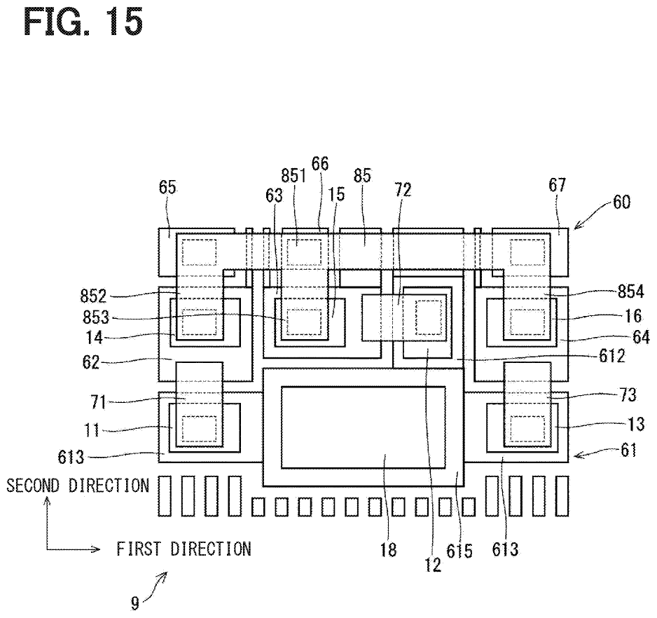

An eighth embodiment is shown in FIG. 14, and a ninth embodiment is shown in FIG. 15. In the eighth embodiment and the ninth embodiment, the chips 11 to 16 are placed flatly, and the control chip 18 is incorporated in a module.

A lead frame 60 of an electronic device 8 according to the eighth embodiment has a power land 61, output lands 62 to 64, and ground lands 65 to 67. The power land 61 has element mounting portions 611 to 613 and an IC mounting portion 615. The element mounting portions 611 and 613 are arranged protruding on both sides of the IC mounting portion 615 in the first direction, and the high-side chips 11 and 13 are arranged on the element mounting portions 611 and 613. The element mounting portion 612 is arranged protruding in the second direction from the IC mounting portion 615, and the high-side chip 12 is arranged on the element mounting portion 612. Drain electrodes of the high-side chips 11 to 13 are connected to the power land 61.

The control chip 18 is arranged on the IC mounting portion 615. Since a back surface side of an element is insulated, the control chip 18 of the present embodiment can be arranged not only on a land at a ground potential but also on a land at a power supply potential as in the present embodiment. Also in embodiments other than the present embodiment, a control chip having an insulated back surface may be used.

The output land 62 is arranged adjacent to the element mounting portion 611 in the second direction. The output land 63 is arranged on the second direction side of the IC mounting portion 615, and between the output land 62 and the element mounting portion 612. The output land 64 is arranged adjacent to the element mounting portion 613 in the second direction. Therefore, the output lands 62 to 64 and the element mounting portion 612 are arranged in order of the output land 62, the output land 63, the element mounting portion 612, and the output land 64 from one side in the first direction.

The low-side chips 14 to 16 are arranged on the output lands 62 to 64, and the drain electrodes of the low-side chips 14 to 16 are connected to the output lands 62 to 64. The intermediate clips 71 to 73 connect sources of the high-side chips 11 to 13 and the output lands 62 to 64, respectively. A ground clip 84 connects sources of the low-side chips 14 to 16 and the ground lands 65 to 67. The ground clip 84 is formed into a substantially rectangular shape, and is formed with a cutout portion 841 at a location where the intermediate clip 72 is arranged.

The chips 11 to 16 are arranged so as to surround three sides of the control chip 18 as a whole. In addition, the clips 71 to 73 and 84 are provided on the chips 11 to 16 in a shifted manner so as not to overlap portions of the chips 11 to 16 adjacent to the control chip 18 thereby allowing connection of various signal lines including a gate signal line connecting a gate electrode and the control chip 18.

An electronic device 9 according to the ninth embodiment shown in FIG. 15 is substantially similar to that of the eighth embodiment except that the shape of a ground clip 85 is different. The ground clip 85 has a ground connection portion 851 connected to the ground lands 65 to 67, and protruding portions 852 to 854 protruding from the ground connection portion 851 in the second direction. The protruding portions 852 to 854 are provided at locations where the low-side chips 14 to 16 are arranged, and are connected to source electrodes of the low-side chips 14 to 16 at a lower surface. In FIG. 15, illustrations of a terminal on a side in the second direction, a terminal on a side adjacent to the ground, and a signal line for a gate connection or the like are omitted. Even with this configuration, the similar effects to those of the above embodiments are achieved.

In the embodiments, the power lands 22, 41, 51, and 61 correspond to a “power supply wiring member”, the ground clips 34 and 81 to 85 correspond to a “ground wiring member”, and the intermediate clips 31 to 33 and 71 to 73 and the output lands 52 to 54 correspond to an “intermediate connection member”. Furthermore, the capacitor 93 corresponds to a “noise suppression element”.

### Other Embodiments

In the embodiments described above, the low-side chips are connected by the ground clip, which is a plate-shaped metal plate. In another embodiment, a member connecting sources of elements on a low potential side is not limited to a metal plate, and ribbon bonding or aluminum bonding may be used. The same applies to a member connecting high-side chips.

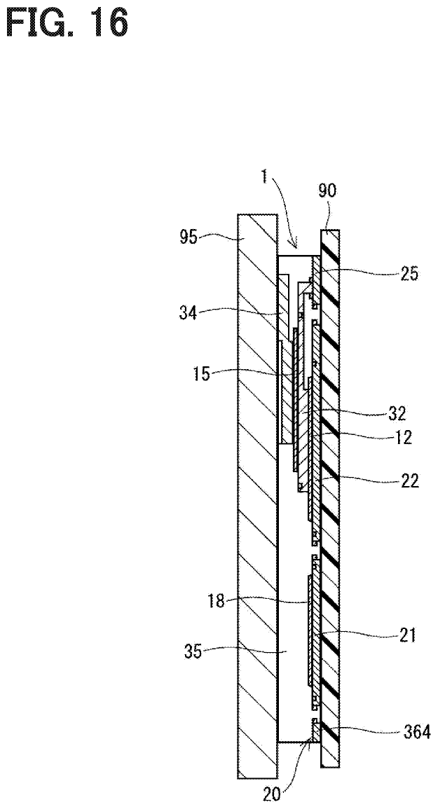

In the embodiments described above, the ground clip is sealed in the sealing part 35. In another embodiment, as shown in FIG. 16, a ground clip may be exposed from a top surface side of a sealing part, such that heat is directly dissipated to a heat dissipation housing. That is, the ground clip is a metal plate connected to the low-side chips on the upper side, and a surface on a side opposite to the low-side chips is exposed from the sealing part 35. Accordingly, heat dissipation efficiency can be improved. Note that FIG. 16 illustrates the electronic device 1 of the first embodiment, but the top surface side of the ground clip may be exposed from the sealing part 35 in embodiments other than the first embodiment.

In the embodiments described above, the noise suppression element is a capacitor. In another embodiment, a noise suppression element may be an element other than a capacitor, such as a snubber circuit, as long as it is an electronic component capable of suppressing noise.

As described above, the present disclosure is not limited to the embodiments described above in any way, and can be implemented in various forms without departing from the spirit thereof.

The present disclosure has been described based on the embodiments. However, the present disclosure is not limited to the embodiments and structures. The present disclosure also encompasses various modifications and variations within equivalent ranges. In addition, various combinations and forms, as well as other combinations and forms including only one element, more elements, or fewer elements, are also within the scope and technical spirit of the present disclosure.

What is claimed is:

1. An electronic device comprising:
a plurality of high-side chips each including an upper arm element connected to a high potential side;
a plurality of low-side chips respectively connected to the plurality of high-side chips to form a plurality of pairs in a module, the plurality of low-side chips each including a lower arm element connected to a low potential side of a corresponding upper arm element;
a power supply wiring member connecting the plurality of high-side chips to a power supply potential;
a ground wiring member connecting the plurality of low-side chips to a ground potential; and
a sealing part sealing the plurality of high-side chips, the plurality of low-side chips, the power supply wiring member, and the ground wiring member integrally, wherein
the ground wiring member is shared by the plurality of low-side chips,
the power supply wiring member is a power land on which the plurality of high-side chips are arranged,
the power land and a ground land connected to the plurality of low-side chips via the ground wiring member have surfaces exposed from the sealing part on a side adjacent to a substrate to be connected to a power supply pattern and a ground pattern of the substrate, respectively, and
the power supply pattern and the ground pattern extend to a back surface of the substrate through vias penetrating the substrate, and are connected to a noise suppression element.

2. The electronic device according to claim 1, wherein
the power supply wiring member is shared by the plurality of high-side chips.

3. The electronic device according to claim 1, further comprising:
a control chip sealed in the sealing part, wherein
the control chip includes a pre-driver integrated circuit configured to output drive signals for the upper arm element and the lower arm element, and
the plurality of high-side chips and the plurality of low-side chips are arranged in an area on one side of the control chip such that gate electrodes of the plurality of high-side chips and the plurality of low-side chips to which the drive signals are input face the control chip.

4. An electronic device comprising:
a plurality of high-side chips each including an upper arm element connected to a high potential side;
a plurality of low-side chips respectively connected to the plurality of high-side chips to form a plurality of pairs in a module, the plurality of low-side chips each including a lower arm element connected to a low potential side of a corresponding upper arm element;
a power supply wiring member connecting the plurality of high-side chips to a power supply potential;
a ground wiring member connecting the plurality of low-side chips to a ground potential;
a sealing part sealing the plurality of high-side chips, the plurality of low-side chips, the power supply wiring member, and the ground wiring member integrally, wherein
the ground wiring member is shared by the plurality of low-side chips, and
an intermediate connection member connecting one of the plurality of high-side chips and a corresponding one of the plurality of low-side chips is composed of two or fewer members.

5. The electronic device according to claim 4, wherein
the one of the plurality of high-side chips, the intermediate connection member, and the corresponding one of the plurality of low-side chips are stacked in this order, and
the one of the plurality of high-side chips and the corresponding one of the plurality of low-side chips are connected on opposite surfaces of the intermediate connection member.

6. The electronic device according to claim 5, wherein
the intermediate connection member and the corresponding one of the plurality of low-side chips are disposed on a top surface side of the one of the plurality of high-side chips, and
the intermediate connection member and the corresponding one of the plurality of low-side chips are stacked in a shifted state such that a part on the top surface side of the one of the plurality of high-side chips does not overlap.

7. The electronic device according to claim 4, wherein
the power supply wiring member is shared by the plurality of high-side chips.

8. The electronic device according to claim 4, wherein
the power supply wiring member is a power land on which the plurality of high-side chips are arranged, and
the power land is arranged adjacent to a ground land connected to the ground wiring member.

9. The electronic device according to claim 4, further comprising:
a control chip sealed in the sealing part, wherein
the control chip includes a pre-driver integrated circuit configured to output drive signals for the upper arm element and the lower arm element, and
the plurality of high-side chips and the plurality of low-side chips are arranged in an area on one side of the control chip such that gate electrodes of the plurality of high-side chips and the plurality of low-side chips to which the drive signals are input face the control chip.

10. An electronic device comprising:
a plurality of high-side chips each including an upper arm element connected to a high potential side;
a plurality of low-side chips respectively connected to the plurality of high-side chips to form a plurality of pairs in a module, the plurality of low-side chips each including a lower arm element connected to a low potential side of a corresponding upper arm element;
a power supply wiring member connecting the plurality of high-side chips to a power supply potential;
a ground wiring member connecting the plurality of low-side chips to a ground potential; and
a sealing part sealing the plurality of high-side chips, the plurality of low-side chips, the power supply wiring member, and the ground wiring member integrally, wherein
the ground wiring member is shared by the plurality of low-side chips,
the ground wiring member is a metal plate connected to a top surface side of the plurality of low-side chips, and
a surface of the metal plate on a side opposite to the plurality of low-side chips is exposed from the sealing part.

11. The electronic device according to claim 10, wherein
the power supply wiring member is shared by the plurality of high-side chips.

12. The electronic device according to claim 10, wherein
the power supply wiring member is a power land on which the plurality of high-side chips are arranged, and
the power land is arranged adjacent to a ground land connected to the ground wiring member.

13. The electronic device according to claim 10, further comprising:
a control chip sealed in the sealing part, wherein
the control chip includes a pre-driver integrated circuit configured to output drive signals for the upper arm element and the lower arm element, and
the plurality of high-side chips and the plurality of low-side chips are arranged in an area on one side of the control chip such that gate electrodes of the plurality of high-side chips and the plurality of low-side chips to which the drive signals are input face the control chip.
